(19) United States
(12) Patent Application Publication
(10) Pub. No.: US 2026/0290481 A1
(43) Pub. Date: Sep. 24, 2026

(54) RECEPTION APPARATUS, MEMORY CONTROLLER, AND MEMORY SYSTEM

(71) Applicant: Kioxia Corporation, Tokyo (JP)

(72) Inventor: Yoichi YOSHIDA, Yokohama Kanagawa (JP)

(73) Assignee: Kioxia Corporation, Tokyo (JP)

(21) Appl. No.: 19/322,803

(22) Filed: Sep. 9, 2025

(30) Foreign Application Priority Data
Mar. 21, 2025 (JP) 2025-046983

(51) Int. Cl. G11C 29/02; G11C 16/26; G11C 16/30; G11C 29/52

(52) U.S. Cl. CPC G11C 29/023; G11C 16/26; G11C 16/30; G11C 29/52

(57) ABSTRACT

A reception apparatus includes a conversion circuit, a plurality of comparison circuits, and a selection circuit. The conversion circuit converts a second digital signal into a third digital signal synchronized with a phase of a first digital signal. The plurality of comparison circuits each shift a bit sequence of the first digital signal by a predetermined number and count a number of bit errors by comparing the bit sequence of the first digital signal shifted by the predetermined number with a bit sequence of the third digital signal. The selection circuit selects any one of the plurality of comparison circuits based on the plurality of numbers of bit errors respectively counted by the plurality of comparison circuits and detects the number of bit errors counted by the selected comparison circuit as an actual number of bit errors.

### CROSS-REFERENCE TO RELATED APPLICATION

This application is based upon and claims the benefit of priority from the prior Japanese Patent Applications No. 2025-46983, filed on Mar. 21, 2025, the entire contents of which are incorporated herein by reference.

### FIELD

Embodiments are related to a reception apparatus, a memory controller, and a memory system.

### BACKGROUND

A reception apparatus used in a memory controller is known.

### BRIEF DESCRIPTION OF THE DRAWINGS

FIG. 1 is a block diagram illustrating a schematic configuration of a memory system of an embodiment;

FIG. 2 is a block diagram illustrating a schematic configuration of a host interface unit of the embodiment;

FIG. 3 is a block diagram illustrating a schematic configuration of a conversion circuit of the embodiment;

FIG. 4 is a block diagram illustrating a schematic configuration of a synchronization circuit of the embodiment;

FIG. 5 is a block diagram illustrating a schematic configuration of an error detection circuit of the embodiment; and

FIG. 6 is a block diagram illustrating a schematic configuration of a comparison circuit of the embodiment.

### DETAILED DESCRIPTION

In general, according to the embodiment, a reception apparatus includes a first sampler circuit, a second sampler circuit, a conversion circuit, a plurality of comparison circuits, and a selection circuit. The first sampler circuit extracts a first digital signal from an input reception signal based on a first clock signal. The second sampler circuit uses the reception signal or a reference signal obtained by performing an adjustment on the reception signal and a second clock signal obtained by performing a phase adjustment on the first clock signal to extract a second digital signal based on the second clock signal from the reception signal or the reference signal. The conversion circuit converts the second digital signal into a third digital signal synchronized with a phase of the first digital signal. The plurality of comparison circuits are each a circuit which shifts a bit sequence of the first digital signal by a predetermined number and counts a number of bit errors by comparing the bit sequence of the first digital signal shifted by the predetermined number with a bit sequence of the third digital signal. The predetermined numbers are set as mutually different numbers. The selection circuit selects any one of the plurality of comparison circuits based on the plurality of numbers of bit errors respectively counted by the plurality of comparison circuits and detects the number of bit errors counted by the selected comparison circuit as an actual number of bit errors.

Hereinafter, embodiments will be described with reference to the drawings. To facilitate understanding of the explanation, in each drawing, the same components are denoted by the same reference numerals as much as possible, and duplicated explanations are omitted.

### 1 Embodiment

A reception apparatus, a memory controller, and a memory system of an embodiment will be described.

### 1.1 Configuration of Memory System

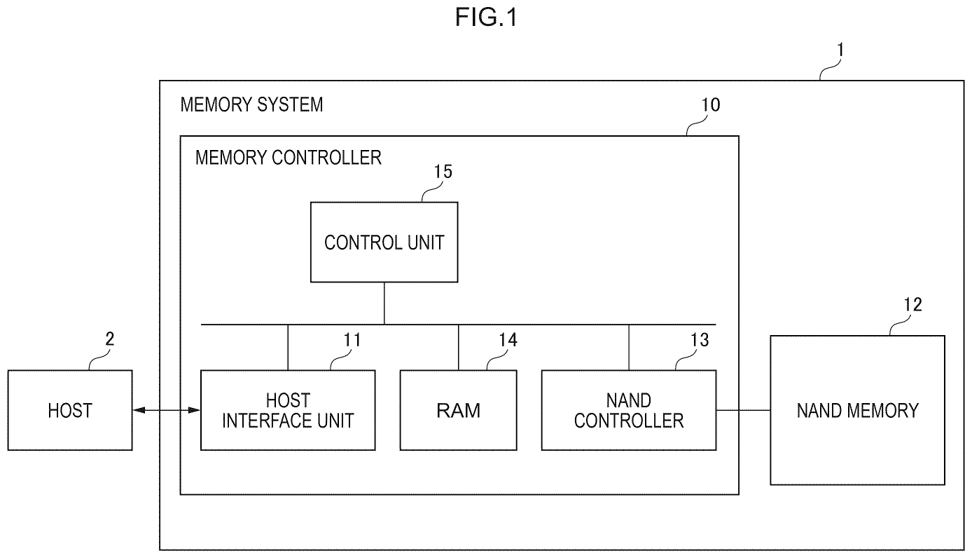

FIG. 1 illustrates an example of a configuration of a memory system of the embodiment. A memory system 1 is configured to be connectable to a host 2. The memory system 1 in a state of being connected to the host 2 executes transmission and reception of data with the host 2 in response to a request from the host 2.

The host 2 is, for example, a personal computer, a mobile information device, or an electronic device such as a server. The host 2 may be a circuit having a function of communicating with a processor included in the electronic device or the memory system 1, instead of the electronic device. Any interface standard can be adopted as an interface standard of communication between the memory system 1 and the host 2. Two or more hosts 2 may be connected to the memory system 1. The host 2 and the memory system 1 may be connected via a network.

The memory system 1 includes a NAND type flash memory (hereinafter, referred to as a NAND memory) 12 and a memory controller 10. The memory system 1 is, for example, a storage device such as a Solid State Drive (SSD) or an Universal Flash Storage (UFS) device. The NAND memory 12 is a nonvolatile storage medium which functions as a storage and is an example of a semiconductor storage device. The NAND memory 12 is configured by one or more chips. The memory controller 10 includes a host interface unit 11, a NAND controller 13, a Random Access Memory (RAM) 14, and a control unit 15.

The control unit 15 is configured by including one or more processors, for example. The control unit 15 executes control of the memory system 1 by executing firmware stored in the memory system 1 in advance. A storage location of a program is optionally designed. For example, the firmware is stored in the NAND memory 12 in advance and loaded to the RAM 14 at the time of activation. The control unit 15 executes the firmware loaded to the RAM 14. The memory system 1 is controlled by a plurality of processes based on the firmware, for example. Some or all of the plurality of processes to be executed by the control unit 15 may be achieved by a hardware circuit. The control unit 15 may be configured by a control circuit serving as the hardware circuit.

The host interface unit 11 is an example of a reception apparatus. The host interface unit 11 is an interface apparatus for the memory system 1 to communicate with the host 2. For example, under control of the control unit 15, the host interface unit 11 executes transfer of user data between the host 2 and the RAM 14.

The NAND controller 13 is an interface apparatus configured to access the NAND memory 12. Under control of the control unit 15, the NAND controller 13 executes transfer of user data or management information between the RAM 14 and the NAND memory 12. Although a detail is omitted, the NAND controller 13 can perform error correction processing.

The RAM 14 is a storage medium configured to temporarily store data. The RAM 14 may be built in the memory controller 10 or mounted outside the memory controller 10. A storage medium which can transmit and receive data at a higher speed than that of the NAND memory 12 can be adopted as the RAM 14, for example. A volatile or nonvolatile storage medium can be adopted as the RAM 14, for example. A Dynamic RAM (DRAM), a Static RAM (SRAM), a Ferroelectric RAM (FeRAM), a Magnetoresistive RAM (MRAM), a Phase-Change RAM (PRAM), or the like can be adopted as the RAM 14, for example.

### 1.2 Configuration of Host Interface Unit

Next, a configuration of the host interface unit 11 will be described.

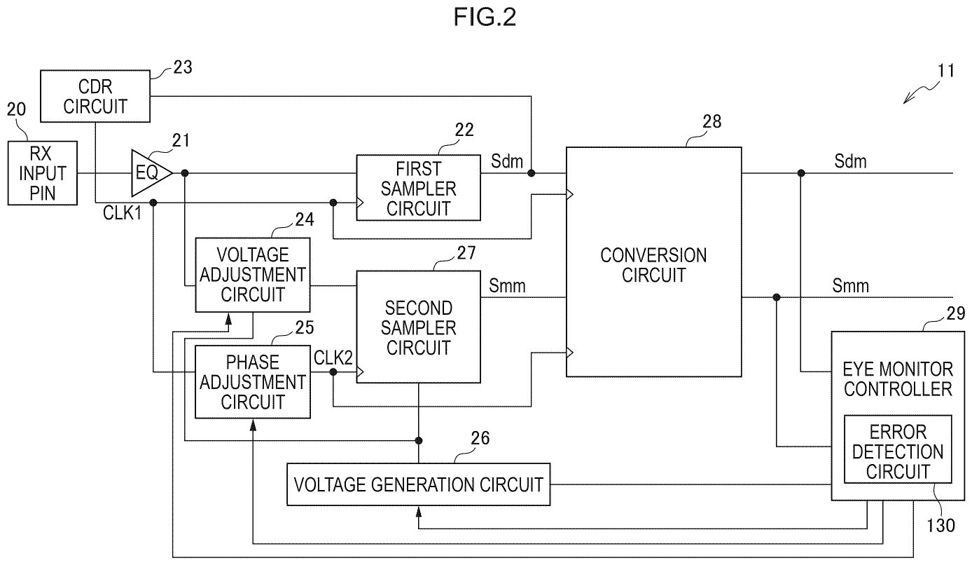

As illustrated in FIG. 2, the host interface unit 11 includes an RX input pin 20, an equalizer 21, a first sampler circuit 22, a clock data recovery (CDR) circuit 23, a voltage adjustment circuit 24, a phase adjustment circuit 25, a voltage generation circuit 26, a second sampler circuit 27, a conversion circuit 28, an eye monitor controller 29, and an error detection circuit 130.

The RX input pin 20 receives a signal transmitted from the host 2. Hereinafter, the signal received by the RX input pin 20 will be referred to as a reception signal. The reception signal is a serial signal having a bus width of 2 bits that differentially operates between two lines in a physical layer of a serial interface, for example. The equalizer 21 performs a compensation such as an amplification of a high frequency component of the reception signal received by the RX input pin 20.

The first sampler circuit 22 extracts binary data included in the reception signal by using a first reference voltage while operating in synchronization with a clock signal CLK1 generated by the CDR circuit 23, and also generates a main data signal Sdm composed of a digital signal including the extracted binary data. Extraction of the binary data from the reception signal by the first sampler circuit 22 is also referred to as “sampling”. The binary data is data of “0” or “1”. The first sampler circuit 22 outputs the generated main data signal Sdm to each of the CDR circuit 23 and the conversion circuit 28.

The CDR circuit 23 obtains the main data signal Sdm output from the first sampler circuit 22 to separate a clock signal from the main data signal Sdm and outputs the separated clock signal CLK1 to the first sampler circuit 22 and the phase adjustment circuit 25. The clock signal CLK1 is, for example, a clock signal of 12 GHz.

The voltage adjustment circuit 24 uses the reception signal output from the equalizer 21 as a reference to generate a reference signal with its voltage adjusted. For example, the voltage adjustment circuit 24 obtains a control code signal generated by the eye monitor controller 29 and generates the reference signal by adjusting the voltage of the reception signal by using an analog reference voltage generated by the voltage generation circuit 26 based on the control code signal. The voltage adjustment circuit 24 outputs the generated reference signal to the second sampler circuit 27. Note that the voltage adjustment circuit 24 may generate the reference signal by adjusting the voltage of the reception signal without using the control code signal generated by the eye monitor controller 29, that is, by using only the analog reference voltage generated by the voltage generation circuit 26.

The phase adjustment circuit 25 uses the clock signal CLK1 generated by the CDR circuit 23 as a reference to generate a clock signal CLK2 with its phase changed. For example, the phase adjustment circuit 25 obtains a control code signal generated by the eye monitor controller 29 and generates the clock signal CLK2 on which the timing adjustment is implemented according to the control code signal. The phase adjustment circuit 25 outputs the generated clock signal CLK2 to the second sampler circuit 27

The voltage generation circuit 26 uses the first reference voltage used in the first sampler circuit 22 as a reference to generate a second reference voltage with its voltage adjusted. For example, the voltage generation circuit 26 obtains a control code signal generated by the eye monitor controller 29 and generates the second reference voltage on which the voltage adjustment is implemented according to the control code signal. The voltage generation circuit 26 outputs the generated second reference signal to the second sampler circuit 27.

The second sampler circuit 27 is a sampler circuit which is provided in tandem with the first sampler circuit 22 to sample a signal waveform including an opening portion of an eye pattern in the reception signal. The second sampler circuit 27 extracts binary data included in the reference signal generated by the voltage adjustment circuit 24 by using the second reference voltage generated by the voltage generation circuit 26 while operating in synchronization with the clock signal CLK2 output from the phase adjustment circuit 25, and also generates a reference data signal Smm composed of a digital signal including the extracted binary data. The second sampler circuit 27 outputs the generated reference data signal Smm to the conversion circuit 28.

The main data signal Sdm generated by the first sampler circuit 22 and the clock signal CLK1 generated by the CDR circuit 23 are input to the conversion circuit 28. The reference data signal Smm generated by the second sampler circuit 27 and the clock signal CLK2 generated by the phase adjustment circuit 25 are input to the conversion circuit 28. The conversion circuit 28 converts each of the main data signal Sdm and the reference data signal Smm from a serial signal into a parallel signal based on the clock signals CLK1 and CLK2. In this manner, the conversion circuit 28 functions as a so-called deserializer which converts a serial signal into a parallel signal. The conversion circuit 28 outputs the main data signal Sdm and the reference data signal Smm which are converted into the parallel signals to the eye monitor controller 29.

The eye monitor controller 29 sets, for example, a phase and a voltage when a signal of a processing target is sampled in the second sampler circuit 27 and also generates a control code signal representing set contents. The eye monitor controller 29 also generates, based on the main data signal Sdm and the reference data signal Smm which are output from the conversion circuit 28, eye monitor data of the entire signal including an eye pattern opening of the reception signal. The eye monitor controller 29 generates the eye monitor data that is data obtained by overlapping a large number of pieces of waveform data in a coordinate plane expanded with a voltage set on the vertical axis and a phase set on the horizontal axis. The generated eye monitor data is displayed, for example, on a display of a personal computer by software for inspection or displayed in another inspection device externally connected to the personal computer when necessary. To create the eye monitor data, the eye monitor controller 29 outputs the control code signal representing the phase or the voltage related to the signal of the extraction target to at least one of the voltage adjustment circuit 24, the phase adjustment circuit 25, and the voltage generation circuit 26. In the present embodiment, the eye monitor controller 29 is an example of a waveform generation circuit.

The error detection circuit 130 is provided in the eye monitor controller 29. The error detection circuit 130 detects the number of bit errors of the main data signal Sdm based on the main data signal Sdm and the reference data signal Smm which are output from the conversion circuit 28. The number of bit errors detected by the error detection circuit 130 is displayed, for example, on the display of the personal computer by the software for inspection or displayed in another inspection device externally connected to the personal computer when necessary.

### 1.2 Configuration of Conversion Circuit

Next, a configuration of the conversion circuit 28 will be described.

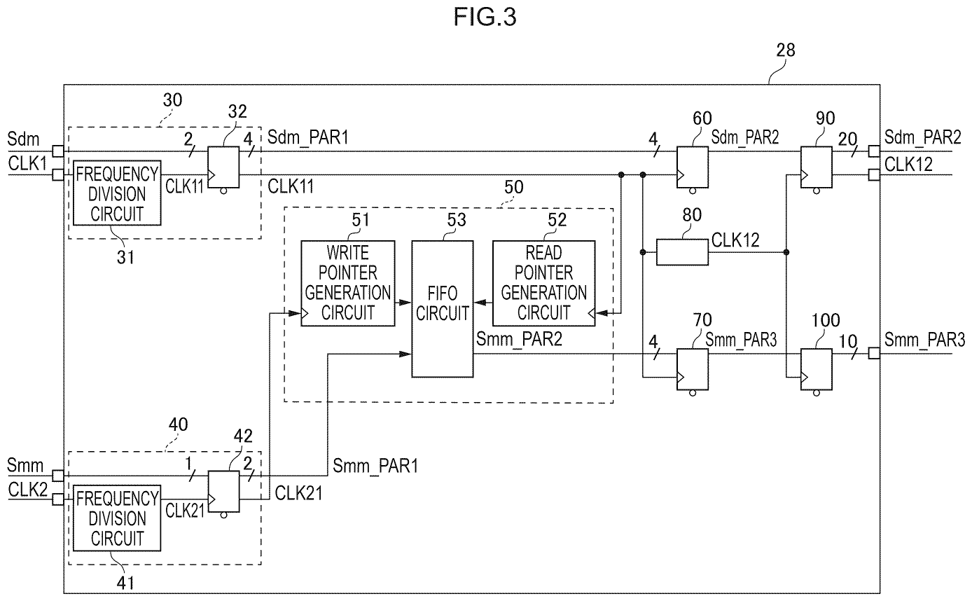

As illustrated in FIG. 3, the conversion circuit 28 includes alignment circuits 30 and 40, a synchronization circuit 50, bus width conversion circuits 60 and 70, a frequency division circuit 80, and output circuits 90 and 100.

The alignment circuit 30 aligns the main data signal Sdm generated by the first sampler circuit 22 to be output as a parallel signal. The alignment circuit 30 includes a frequency division circuit 31 and a shift register circuit 32.

The frequency division circuit 31 divides the clock signal CLK1 to generate a clock signal CLK11. For example, the frequency division circuit 31 generates a clock signal CLK11 of 6 GHz by dividing the clock signal CLK1 of 12 GHz by 2. The frequency division circuit 31 outputs the generated clock signal CLK11 to the shift register circuit 32.

The shift register circuit 32 obtains the main data signal Sdm generated by the first sampler circuit 22. In a case where the main data signal Sdm is a signal that differentially operates between two lines, the bus width is 2 bits. The shift register circuit 32 converts the main data signal Sdm from a serial digital signal into an aligned n-bit parallel digital signal while operating in synchronization with the clock signal CLK11 generated by the frequency division circuit 31. The shift register circuit 32 is configured by a plurality of flip-flop circuits connected in cascade, for example. For example, the n-bit is 2 bits. Hereinafter, the main data signal Sdm converted into to the n-bit parallel signal by the shift register circuit 32 will be referred to as “Sdm_PAR1”. The shift register circuit 32 outputs the main data signal Sdm_PAR1 converted into the parallel signal to the bus width conversion circuit 60 together with the clock signal CLK11. In a case where the main data signal Sdm_PAR1 is a 2-bit parallel signal and is a signal that differentially operates between two lines, the bus width is 4 bits. The shift register circuit 32 also outputs the clock signal CLK11 to the synchronization circuit 50, the bus width conversion circuit 70, and the frequency division circuit 80.

The bus width conversion circuit 60 increases the bus width of the main data signal Sdm_PAR1 generated by the alignment circuit 30 while operating in synchronization with the clock signal CLK11 generated by the frequency division circuit 31. The bus width conversion circuit 60 is configured by a plurality of flip-flop circuits connected in cascade, for example. The bus width conversion circuit 60 converts the main data signal Sdm_PAR1 composed of the n-bit parallel signal into an m-bit parallel signal. Herein, m is an integer larger than n and is, for example, 10 bits. Hereinafter, the main data signal Sdm converted into to the m-bit parallel signal by the bus width conversion circuit 60 will be referred to as “Sdm_PAR2”. In a case where the main data signal Sdm_PAR2 is a 10-bit parallel signal and is a signal that differentially operates between two lines, the bus width is 20 bits.

The frequency division circuit 80 further divides the clock signal CLK11 generated by the frequency division circuit 31 to generate a clock signal CLK12. For example, the frequency division circuit 80 generates a clock signal CLK12 of 1.2 GHz by dividing the clock signal CLK11 of 6 GHz by 5. The frequency division circuit 80 outputs the generated clock signal CLK12 to each of the output circuits 90 and 100.

The output circuit 90 outputs the main data signal Sdm_PAR2 generated by the bus width conversion circuit 60 together with the clock signal CLK12 while operating in synchronization with the clock signal CLK12 generated by the frequency division circuit 80. The main data signal Sdm_PAR2 and the clock signal CLK12 which are output from the output circuit 90 are input to the eye monitor controller 29 illustrated in FIG. 1.

The alignment circuit 40 aligns the reference data signal Smm generated by the second sampler circuit 27 to be output as a parallel signal. The alignment circuit 40 includes a frequency division circuit 41 and a shift register circuit 42.

The frequency division circuit 41 divides the clock signal CLK2 to generate a clock signal CLK21. For example, the frequency division circuit 41 generates the clock signal CLK21 of 6 GHz by dividing the clock signal CLK2 of 12 GHz by 2. The frequency division circuit 41 outputs the generated clock signal CLK21 to the shift register circuit 42.

The shift register circuit 42 obtains the reference data signal Smm generated by the second sampler circuit 27. The reference data signal Smm is, for example, a serial signal having a bus width of 1 bit. The shift register circuit 42 converts the reference data signal Smm from a serial digital signal into an aligned n-bit parallel digital signal while operating in synchronization with the clock signal CLK21 generated by the frequency division circuit 41. The shift register circuit 42 is configured by a plurality of flip-flop circuits connected in cascade, for example. Hereinafter, the reference data signal Smm converted into to the n-bit parallel signal by the shift register circuit 42 will be referred to as “Smm_PAR1”. The reference data signal Smm_PAR1 has a bus width of 2 bits, for example. The shift register circuit 42 outputs the reference data signal Smm_PAR1 converted into the parallel signal to the synchronization circuit 50 together with the clock signal CLK21.

The synchronization circuit 50 is a circuit configured to synchronize a phase of the reference data signal Smm_PAR1 generated by the shift register circuit 42 with the clock signal CLK11 of the main data signal Sdm_PAR1. The synchronization circuit 50 includes a write pointer generation circuit 51, a read pointer generation circuit 52, and a First-In First-Out (FIFO) circuit 53.

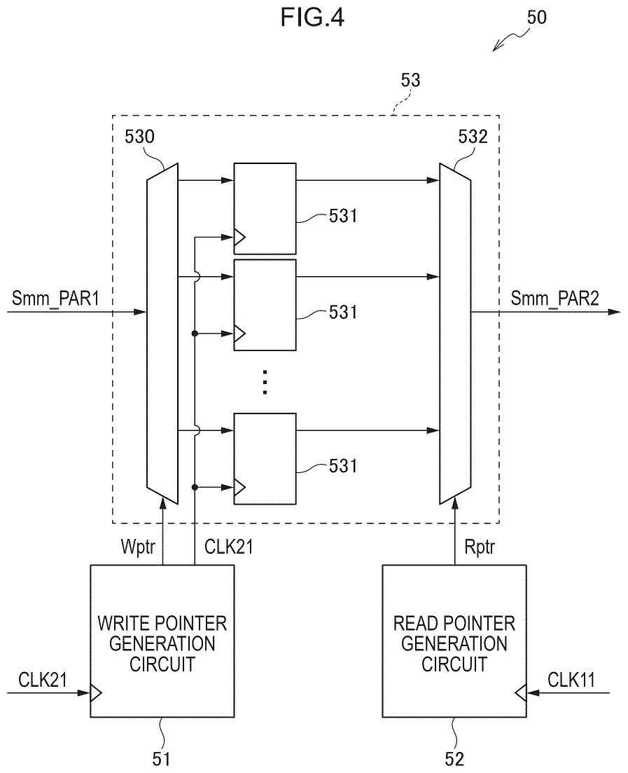

As illustrated in FIG. 4, the FIFO circuit 53 includes a multiplexer circuit 530, a plurality of flip-flop circuits 531, and a multiplexer circuit 532.

The multiplexer circuit 530 selects any of the plurality of flip-flop circuits 531 as a write target of data based on a write pointer Wptr generated by the write pointer generation circuit 51. The multiplexer circuit 530 outputs data included in the reference data signal Smm_PAR1 to the selected flip-flop circuit to be held.

Each of the flip-flop circuits 531 obtains data transmitted from the multiplexer circuit 530. Each of the flip-flop circuits 531 takes in the data obtained from the multiplexer circuit 530 at a timing when the clock signal CLK21 rises from “L” level to “H” level and holds the data that has been taken in. In the present embodiment, the flip-flop circuit 531 is an example of a storage element.

The multiplexer circuit 532 selects any of the plurality of flip-flop circuits 531 as a readout target based on a read pointer Rptr generated by the read pointer generation circuit 52 and obtains the data from the selected flip-flop circuit. The multiplexer circuit 532 also outputs the data from the selected flip-flop circuit at a timing when the read pointer Rptr is incremented.

The write pointer generation circuit 51 generates the write pointer Wptr based on the clock signal CLK21 and outputs the write pointer Wptr to the multiplexer circuit 530. The write pointer generation circuit 51 increments the write pointer Wptr at a timing when the clock signal CLK21 rises from “L” level to “H” level. The write pointer Wptr is a signal for designating any of the plurality of flip-flop circuits 531 to which the data included in the reference data signal Smm_PAR1 is to be taken in. Since the write pointer Wptr is incremented, the flip-flop circuits 531 to be set as a write target of the data are sequentially switched. The write pointer generation circuit 51 starts its operation based on a start signal generated by the eye monitor controller 29, in more detail, based on a signal obtained by synchronizing the start signal with the clock signal CLK21 through the synchronization circuit or the like.

The read pointer generation circuit 52 generates the read pointer Rptr based on the clock signal CLK11. The read pointer generation circuit 52 increments the read pointer Rptr at a timing when the clock signal CLK11 rises from “L” level to “H” level. The read pointer Rptr is a signal for designating any of the plurality of flip-flop circuits 531 from which the data is to be read out by the multiplexer circuit 532. Since the read pointer Rptr is incremented, the flip-flop circuits 531 to be set as a readout target of the data are sequentially switched. An order in which the flip-flop circuits 531 to be set as the readout target of the data are sequentially switched is the same as an order in which the flip-flop circuits 531 to be set as the write target of the data are sequentially switched. According to this, a first-in first-out operation of the data in the FIFO circuit 53 is achieved. The read pointer generation circuit 52 starts its operation based on a start signal generated by the eye monitor controller 29, in more detail, based on a signal obtained by synchronizing the start signal with the clock signal CLK11 through the synchronization circuit or the like.

With the above-described configuration, the synchronization circuit 50 generates, by the FIFO circuit 53, the reference data signal Smm composed of the n-bit parallel signal in synchronization with the clock signal CLK11. Hereinafter, the reference data signal Smm in synchronization with the clock signal CLK11 which is generated by this synchronization circuit 50 will be referred to as “Smm_PAR2”. The reference data signal Smm_PAR2 has, for example, two-bit bus width.

The bus width conversion circuit 70 illustrated in FIG. 3 increases the bus width of the reference data signal Smm_PAR2 by the synchronization circuit 50 while operating in synchronization with the clock signal CLK11 generated by the frequency division circuit 31. The bus width conversion circuit 70 is configured by a plurality of flip-flop circuits connected in cascade, for example. The bus width conversion circuit 70 converts the reference data signal Smm_PAR2 composed of the n-bit parallel signal into an m-bit parallel signal similarly as in the bus width conversion circuit 60. Hereinafter, the reference data signal Smm converted into to the m-bit parallel signal by the bus width conversion circuit 70 will be referred to as “Smm_PAR3”. The reference data signal Smm_PAR3 has, for example, a 10-bit bus width.

The output circuit 100 outputs the reference data signal Smm_PAR3 generated by the bus width conversion circuit 70 while operating in synchronization with the clock signal CLK12 generated by the frequency division circuit 80. The reference data signal Smm_PAR3 output from the output circuit 90 is input to the eye monitor controller 29 illustrated in FIG. 2.

### 1.3 Configuration of Error Detection Circuit

Next, before a configuration of the error detection circuit 130 is described, a principle of the error detection circuit 130 of the present embodiment is described.

In a case where the conversion circuit 28 as illustrated in FIG. 3 is used, a shift may occur between a bit sequence of the main data signal Sdm_PAR2 and a bit sequence of the reference data signal Smm_PAR3 which are eventually output from the conversion circuit 28. For this reason, to detect the number of bit errors by comparing the bit sequence of the main data signal Sdm_PAR2 with the bit sequence of the reference data signal Smm_PAR3 in the error detection circuit 130, a shift amount between the bit sequence of the main data signal Sdm_PAR2 and the bit sequence of the reference data signal Smm_PAR3 needs to be corrected. For example, in a case where the bit sequence of the reference data signal Smm_PAR3 is delayed by 4 bits with respect to the bit sequence of the main data signal Sdm_PAR2, to appropriately detect the number of bit errors, the bit sequence of the main data signal Sdm_PAR2 needs to be delayed by 4 bits to compare the bit sequence of the main data signal Sdm_PAR2 with the bit sequence of the reference data signal Smm_PAR3.

On the other hand, for example, in a case where a bit shift amount of 44 bits occurs between the bit sequence of the main data signal Sdm_PAR2 and the bit sequence of the reference data signal Smm_PAR3, when the main data signal Sdm_PAR2 is delayed by 4 bits, the bit sequence of the main data signal Sdm_PAR2 and the bit sequence of the reference data signal Smm_PAR3 which are shifted by 40 bits are compared with each other. For this reason, if the reception signal repeats a same pattern in a 20-bit cycle, when the main data signal Sdm_PAR2 shifted by 40 bits and the reference data signal Smm_PAR3 are compared with each other, even though bit data at locations actually shifted by 40 bits are compared with each other, there is a possibility of erroneous recognition that those signals Sdm_PAR2 and Smm_PAR3 are consistent with each other.

In view of the above, while a plurality of bit shift amounts that may occur between the main data signal Sdm_PAR2 and the reference data signal Smm_PAR3 are assumed in advance, a plurality of comparison circuits respectively corresponding to the plurality of assumed bit shift amounts are provided in the error detection circuit 130 of the present embodiment. The respective comparison circuits count the numbers of the bit errors respectively corresponding to the plurality of assumed bit shift amounts. In the error detection circuit 130 of the present embodiment, a comparison circuit with the smallest number of counted bit errors is selected among the plurality of comparison circuits, and the number of bit errors counted by the selected comparison circuit is detected as an actual number of bit errors. According to this configuration, while the number of bit errors rapidly increases in the comparison circuit in which the set bit shift amount is incorrect, since the number of bit errors hardly increases in the comparison circuit in which the set bit shift amount is appropriate, by selecting the comparison circuit with the smallest number of counted bit errors, an appropriate comparison circuit can be selected, and it is also possible to output the more appropriate number of bit errors. In addition, for example, even in a case where a situation occurs where the reception signal repeats a similar pattern in a predetermined cycle, if the situation is temporary, the number of bit errors rapidly increases in the comparison circuit in which the set bit shift amount is incorrect as a result. For this reason, by selecting the comparison circuit with the smallest number of counted bit errors, the appropriate comparison circuit can be selected, and it is also possible to output the more appropriate number of bit errors.

Hereinafter, an example of the configuration of the error detection circuit 130 configured based on the above-described principle will be described. First, the bit shift amount assumed in the conversion circuit 28 of the present embodiment will be specifically described.

In a case where the conversion circuit 28 as illustrated in FIG. 3 is used, a shift may occur between the bit sequence of the main data signal Sdm_PAR2 and the bit sequence of the reference data signal Smm_PAR3 which are eventually output from the conversion circuit 28.

In the conversion circuit 28 as illustrated in FIG. 3, for example, a rising edge of the clock signal CLK11 output from the frequency division circuit 31 and a rising edge of the clock signal CLK21 output from the frequency division circuit 41 may be in opposite phases. In this case, the bit sequence of the reference data signal Smm_PAR1 generated by the shift register circuit 42 may be shifted by 2 bits with respect to the bit sequence of the main data signal Sdm_PAR1 generated by the shift register circuit 32.

In the conversion circuit 28 of the present embodiment, for example, the reference data signal Smm_PAR2 may be shifted by three cycles in the FIFO circuit 53. A shift of one cycle causes a shift of 4 bits. For this reason, a shift of 12 bits may be further caused between the bit sequence of the main data signal Sdm_PAR1 and the bit sequence of the reference data signal Smm_PAR2 generated by the FIFO circuit 53.

When the above is taken into account, in a case where the rising edge of the clock signal CLK11 and the rising edge of the clock signal CLK21 are in positive phases, a shift of 12 bits may occur between the bit sequence of the main data signal Sdm_PAR2 and the bit sequence of the reference data signal Smm_PAR3 which are eventually output from the conversion circuit 28. On the other hand, in a case where the rising edge of the clock signal CLK11 and the rising edge of the clock signal CLK21 are in opposite phases, a shift of 10 bits may occur between the bit sequence of the main data signal Sdm_PAR2 and the bit sequence of the reference data signal Smm_PAR3 which are eventually output from the conversion circuit 28.

Furthermore, in the synchronization circuit 50, for example, a start timing of an operation of the read pointer generation circuit 52 may be delayed with respect to a start timing of an operation of the write pointer generation circuit 51. Every time this delay is increased by one cycle, the bit shift amount of the bit sequence of the reference data signal Smm_PAR2 generated by the FIFO circuit 53 is increased by 4 bits. For example, in a case where the start timing of the operation of the read pointer generation circuit 52 is delayed by one cycle with respect to the start timing of the operation of the write pointer generation circuit 51, the bit sequence of the reference data signal Smm_PAR2 generated by the FIFO circuit 53 is shifted by 4 bits with respect to the bit sequence of the main data signal Sdm_PAR1. Therefore, in a case where the 4-bit shift further occurs due to the shift of those start timings and a case where the rising edge of the clock signal CLK11 and the rising edge of the clock signal CLK21 are in positive phases, a shift of 16 bits may occur between the bit sequence of the main data signal Sdm_PAR2 and the bit sequence of the reference data signal Smm_PAR3 which are eventually output from the conversion circuit 28. In a case where the 4-bit shift further occurs due to the shift of those start timings and a case where the rising edge of the clock signal CLK11 and the rising edge of the clock signal CLK21 are in opposite phases, a shift of 14 bits may occur between the bit sequence of the main data signal Sdm_PAR2 and the bit sequence of the reference data signal Smm_PAR3 which are eventually output from the conversion circuit 28.

In this manner, in a case where the conversion circuit 28 of the present embodiment is used, any of shifts of 10 bits, 12 bits, 14 bits, and 16 bits may occur between the bit sequence of the main data signal Sdm_PAR2 and the bit sequence of the reference data signal Smm_PAR3 which are eventually output from the conversion circuit 28. Hereinafter, the bit shift amounts assumed to occur between the bit sequence of the main data signal Sdm_PAR2 and the bit sequence of the reference data signal Smm_PAR3 are more generalized to be denoted as N+M(0), N+M(1), . . . , N+M(k). Note that k is any integer higher than or equal to 1. In a case where 10 bits, 12 bits, 14 bits, and 16 bits described above are used as the bit shift amounts, for example, k is set as 3, N is set as 10 bits, and furthermore, M(0), M(1), M(2), and M(3) are set as 0 bits, 2 bits, 4 bits, and 6 bits, respectively. The respective bit shift amounts N+M(0), N+M(1), . . . , N+M(k) are set as mutually different values.

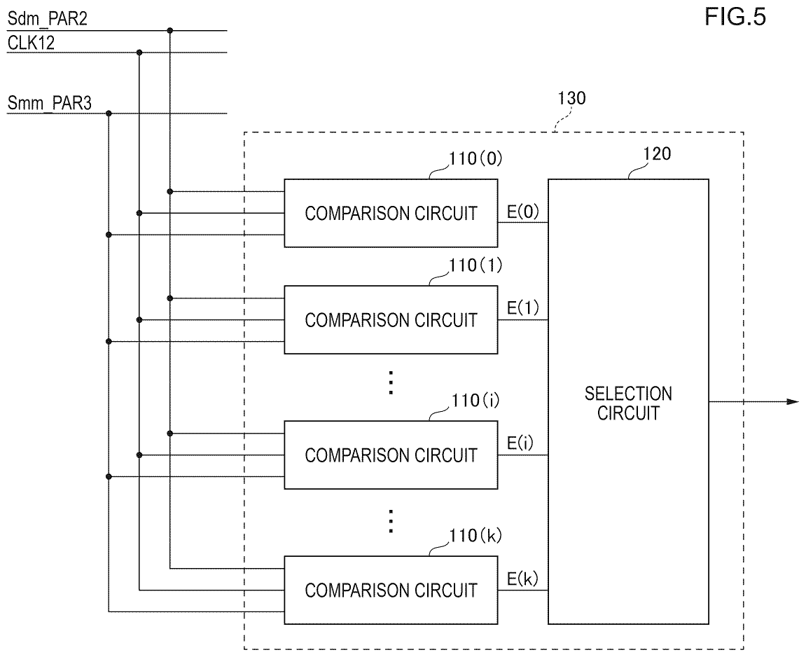

As illustrated in FIG. 5, the error detection circuit 130 includes a plurality of comparison circuits 110(0) to 110(k) and a selection circuit 120. Note that since respective structures of the plurality of comparison circuits 110(0) to 110(k) are the same or similar, hereinafter, one comparison circuit 110(i) among those will be described in a representative manner.

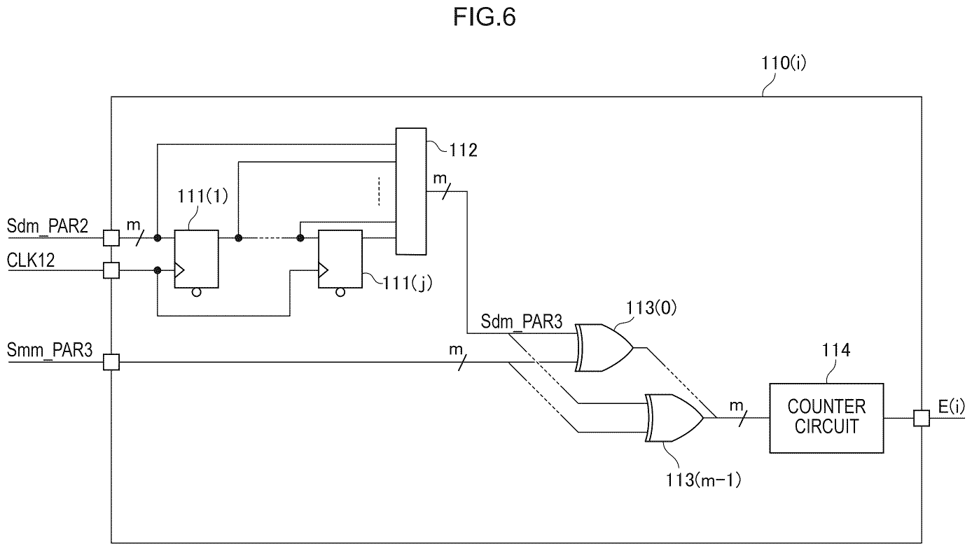

The main data signal Sdm_PAR2 composed of the parallel signal having the bus width of m bits, the reference data signal Smm_PAR3 composed of the parallel signal having the bus width of m bits, and the clock signal CLK12 are input to the comparison circuit 110(i). The comparison circuit 110(i) shifts the bit sequence of the main data signal Sdm_PAR2 by a predetermined number of bits N+M(i), specifically, delays the bit sequence of the main data signal Sdm_PAR2 by the predetermined number of bits N+M(i) to be compared with the bit sequence of the reference data signal Smm_PAR3. As illustrated in FIG. 6, the comparison circuit 110(i) includes a plurality of flip-flop circuits 111(1) to 111(j), a selection circuit 112, a plurality of XOR (exclusive OR) circuits 113(0) to 113(m-1), and a counter circuit 114.

The plurality of flip-flop circuits 111(1) to 111(j) are mutually connected in cascade. The clock signal CLK12 is input to each of the flip-flop circuits 111(1) to 111(j). Each of the flip-flop circuits 111(1) to 111(j) delays the input signal by one cycle to be output. For example, the flip-flop circuits 111(16) delays the main data signal Sdm_PAR2 by 16 cycles, in other words, shifts the bit sequence of the main data signal Sdm_PAR2 by 16 bits to be output. Therefore, the number of the flip-flop circuits 111(1) to 111(j), in other words, a value of j is set in advance according to the bit shift amount assumed in the conversion circuit 28. With regard to the plurality of flip-flop circuits 111(1) to 111(j), m sets are provided to respectively correspond to the m-bit parallel data included in the main data signal Sdm_PAR2.

The main data signal Sdm_PAR2 and outputs of the plurality of respective flip-flop circuits 111(1) to 111(j) are input to the selection circuit 112. The selection circuit 112 is a circuit configured to select any m bits that are shifted by the number of bits N+M(i) with respect to the bit sequence of the main data signal Sdm_PAR2 and that are continuous from among the outputs of the plurality of respective flip-flop circuits 111(1) to 111(j). A main data signal Sdm_PAR3 is a parallel signal having a bus width of m bits.

The plurality of XOR circuits 113(0) to 113(m-1) respectively calculate XOR of parallel data of m bits included in the main data signal Sdm_PAR3 and parallel data of m bits included in the reference data signal Smm_PAR3. Therefore, each of the XOR circuits 113(0) to 113(m-1) outputs “0” in a case where the data included in the corresponding main data signal Sdm_PAR3 and the data included in the corresponding reference data signal Smm_PAR3 are consistent with each other and outputs “1” in a case where those are not consistent with each other.

Each time each of the XOR circuits 113(0) to 113(m-1) outputs “1”, the counter circuit 114 counts the number of times. According to this, the counter circuit 114 counts the number of data between the data included in the corresponding main data signal Sdm_PAR3 and the data included in the corresponding reference data signal Smm_PAR3 that are not consistent with each other. The counter circuit 114 outputs the counted number to the selection circuit 120 as a number of bit errors E(i).

In accordance with the configuration of the comparison circuit 110(i) as described above, each of the plurality of comparison circuits 110(0) to 110(k) illustrated in FIG. 5 outputs the numbers of bit errors E(0), E(1), . . . , E(k) corresponding to the bit shift amounts N+M(0), N+M(1), . . . , N+M(k) to the selection circuit 120.

The selection circuit 120 selects any one of the comparison circuits 110(0) to 110(k) based on the numbers of bit errors E(0), E(1), . . . , E(k) respectively output from the comparison circuits 110(0) to 110(k). For example, the selection circuit 120 selects the comparison circuit that outputs the smallest number of bit errors among the numbers of bit errors E(0), E(1), . . . , E(k). Hereinafter, the comparison circuit selected in the above-described manner will be referred to as a selection comparison circuit 110. After the selection comparison circuit 110 is extracted as described above, the selection circuit 120 detects the number of bit errors output from the extracted selection comparison circuit 110 as the actual number of bit errors.

### 1.4 Action and Effects of Embodiment

As described above, the host interface unit 11 (reception apparatus) of the present embodiment includes the first sampler circuit 22, the second sampler circuit 27, the conversion circuit 28, the plurality of comparison circuits 110(0) to 110(k), and the selection circuit 120. The first sampler circuit 22 extracts the main data signal Sdm (first digital signal) from the input reception signal based on the clock signal CLK1 (first clock signal). The second sampler circuit 27 uses the reference signal obtained by performing the voltage adjustment on the reception signal and the clock signal CLK2 (second clock signal) obtained by performing the phase adjustment on the clock signal CLK1 to extract the reference data signal Smm (second digital signal) from the reference signal based on the clock signal CLK2. The conversion circuit 28 converts the reference data signal Smm into the reference data signal Smm_PAR3 (third digital signal) synchronized with the phase of the main data signal Sdm_PAR2. The plurality of comparison circuits 110(0) to 110(k) are circuits which shift the bit sequence of the main data signal Sdm_PAR2 by predetermined numbers and compare the bit sequence of the main data signal Sdm_PAR3 shifted by the predetermined numbers N+M(0), N+M(1), . . . , N+M(k) with the bit sequence of the reference data signal Smm_PAR3 to respectively count the numbers of bit errors E(0), E(1), . . . , E(k). The predetermined numbers N+M(0), N+M(1), . . . , N+M(k) are set as mutually different values. The selection circuit 120 selects any one of the plurality of comparison circuits 110(0) to 110(k) based on the plurality of numbers of bit errors E(0), E(1), . . . , E(k) respectively counted by the plurality of comparison circuits 110(0) to 110(k) and detects the number of bit errors counted by the selected comparison circuit 110 as the actual number of bit errors.

According to this configuration, it is possible to more appropriately detect the number of bit errors of the reception signal.

The conversion circuit 28 generates the reference data signal Smm_PAR3 by increasing the bus width of the reference data signal Smm. The conversion circuit 28 includes the FIFO (first-In first-out) circuit 53. The FIFO circuit 53 sequentially takes in data included in the reference data signal Smm_PAR1 to be stored in the plurality of flip-flop circuits 531 and also sequentially reads out the data respectively stored in the plurality of flip-flop circuits 531 to be output as the reference data signal Smm_PAR2. The plurality of flip-flop circuits 531 sequentially takes in, based on the clock signal CLK21 corresponding to the reference data signal Smm_PAR1, the data included in the reference data signal Smm_PAR1 to be stored. The FIFO circuit 53 sequentially reads out, based on the clock signal CLK11 corresponding to the main data signal Sdm_PAR1, the data respectively stored in the plurality of flip-flop circuits 531 to be output as the reference data signal Smm_PAR2. The clock signal CLK21 corresponding to the reference data signal Smm_PAR1 is a clock signal obtained by dividing the clock signal CLK2.

In a case where the FIFO circuit 53 described above is used, since the bit sequence of the reference data signal Smm is delayed with respect to the bit sequence of the main data signal Sdm, a significance of using such a configuration of the above-described embodiment is large.

The predetermined numbers N+M(0), N+M(1), . . . , N+M(k) are set as values that meet 2a when “a” is set as an integer, such as 10 bits, 12 bits, 14 bits, and 16 bits.

According to this configuration, it is possible to more appropriately set the bit shift amount of the bit sequence of the reference data signal Smm with respect to the bit sequence of the main data signal Sdm.

The selection circuit 120 selects the comparison circuit with the smallest number of bit errors from among the plurality of comparison circuits 110(0) to 110(k).

According to this configuration, it is possible to more appropriately select the comparison circuit corresponding to the actual bit shift amount.

The host interface unit 11 further includes the eye monitor controller 29 (waveform generation circuit). The eye monitor controller 29 generates a waveform of an eye pattern by comparing the reference data signal Smm with the reference voltage.

According to this configuration, it is possible to easily obtain the waveform of the eye pattern.

### 1.5 First Modified Example

Next, a first modified example of the memory system 1 of the above-described embodiment will be described.

The selection circuit 120 can use any method as a method of selecting one comparison circuit with a small number of bit errors from among the plurality of comparison circuits 110(0) to 110(k). For example, in a case where an upper limit exists on the number of allowable errors in the error detection circuit 130, an error count value (number of bits) in the counter circuit 114 is set as the same value as the upper limit of the number of allowable errors or a value slightly larger than the above-described value, and an overflow flag is further provided for the error count. The overflow flag is binary bit data which is set to an off state (for example, “0”) when the value of the error count does not exceed the upper limit and set to an on state (for example, “1”) when the value of the error count exceeds the upper limit. According to such a configuration, it is assumed that only one comparison circuit in which the value of the error count does not overflow remains among the plurality of comparison circuits 110(0) to 110(k). For this reason, for example, the comparison circuit in which the overflow flag is in the off state among the plurality of comparison circuits 110(0) to 110(k) may be decided as the selection comparison circuit 110.

Note that in a case where the comparison circuit in which the value of the error count does not overflow does not exist among the plurality of comparison circuits 110(0) to 110(k), the selection circuit 120 may change the number of bits of the error count or execute processing of returning an error to the host 2, or the like.

Counting up of the errors in the comparison circuits 110(0) to 110(k) may be stopped based on such a setting, for example, that all numbers of bits of the error count are set as “1” in binary without implementing the overflow flag. According to this configuration, for example, the comparison circuit in which all numbers of bits of the error count are not set as “1” among the plurality of comparison circuits 110(0) to 110(k) may be decided as the selection comparison circuit 110.

### 1.6 Second Modified Example

Next, a second modified example of the memory system 1 of the above-described embodiment will be described.

In the memory system 1 in the present modified example, when the comparison circuit 110(i) starts to create the eye monitor data, the error count value (number of bits) in the counter circuit 114 is set as the same value as the upper limit of the number of allowable errors or a value slightly larger than the above-described value. The comparison circuit 110(i) counts down the number of bits of error count each time the bit error is detected. The comparison circuit 110(i) then stops counting down the number of bits of error count when all numbers of bits of the error count are set as “0” in binary. According to this configuration, it is assumed that only one comparison circuit in which all numbers of bits of the error count are not set as “0” remains among the plurality of comparison circuits 110(0) to 110(k). For this reason, for example, the comparison circuit in which all numbers of bits of the error count are not “0” in binary among the plurality of comparison circuits 110(0) to 110(k) may be decided as the selection comparison circuit 110.

Note that in a case where the comparison circuit in which all numbers of bits of the error count are not “0” does not exist among the plurality of comparison circuits 110(0) to 110(k), the selection circuit 120 may change the number of bits of the error count or execute processing of returning an error to the host 2, or the like.

### 2 Other Embodiments

The present disclosure is not limited to the above-described specific examples.

For example, in the host interface unit 11, the reception signal output from the equalizer 21 may be input to the second sampler circuit 27 as it is as the reference signal.

Some of the embodiments of the present invention have been described, but these embodiments are presented as examples and are not intended to limit the scope of the invention. These novel embodiments may be implemented by various other modes, and various types of omissions, substitutions, and modifications can be made without departing from the gist of the invention. These embodiments and modifications thereof are included in the scope and gist of the invention and included in the scope of the invention described in the claims and its equivalents.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A reception apparatus comprising:
a first sampler circuit configured to extract a first digital signal based on a first clock signal from an input reception signal;
a second sampler circuit which uses the reception signal or a reference signal obtained by performing an adjustment on the reception signal and a second clock signal obtained by performing a phase adjustment on the first clock signal to extract a second digital signal based on the second clock signal from the reception signal or the reference signal;
a conversion circuit which converts the second digital signal into a third digital signal synchronized with a phase of the first digital signal;
a plurality of comparison circuits each of which is a circuit which shifts a bit sequence of the first digital signal by a predetermined number and counts a number of bit errors by comparing the bit sequence of the first digital signal shifted by the predetermined number with a bit sequence of the third digital signal and in which the predetermined number is set as a mutually different value; and
a selection circuit which selects any one of the plurality of comparison circuits based on the plurality of numbers of bit errors respectively counted by the plurality of comparison circuits and detects the number of bit errors counted by the selected comparison circuit as an actual number of bit errors.

2. The reception apparatus according to claim 1, wherein
the conversion circuit is a bus width conversion circuit which generates the third digital signal by increasing a bus width of the second digital signal.

3. The reception apparatus according to claim 1, wherein
the conversion circuit includes
a first-in first-out circuit which sequentially takes in data included in the second digital signal to be stored in a plurality of storage elements and sequentially reads out the data respectively stored in the plurality of storage elements to be output as the third digital signal,
the plurality of storage elements sequentially take in the data included in the second digital signal to be stored based on a clock signal corresponding to the second digital signal, and
the first-in first-out circuit sequentially reads out the data respectively stored in the plurality of storage elements to be output as the third digital signal based on a clock signal corresponding to the first digital signal.

4. The reception apparatus according to claim 3, wherein
the clock signal corresponding to the second digital signal is a clock signal obtained by dividing the second clock signal.

5. The reception apparatus according to claim 1, wherein
when “a” is set as an integer, the predetermined number is a value that meets 2a.

6. The reception apparatus according to claim 1, wherein
the selection circuit selects the comparison circuit with the smallest number of bit errors from among the plurality of comparison circuits.

7. The reception apparatus according to claim 1, wherein
the selection circuit selects the comparison circuit in which the number of bit errors does not exceed a predetermined upper limit from among the plurality of comparison circuits.

8. The reception apparatus according to claim 1, further comprising:
a waveform generation circuit which generates a waveform of an eye pattern by comparing the second digital signal with a reference voltage.

9. The reception apparatus according to claim 1, wherein
the second sampler circuit uses a reference signal obtained by performing a voltage adjustment on the reception signal as the reference signal.

10. A memory controller which is connectable to a host and controls a semiconductor storage device, the memory controller comprising:
a first sampler circuit configured to extract a first digital signal based on a first clock signal from a reception signal transmitted from the host;
a second sampler circuit which uses the reception signal or a reference signal obtained by performing an adjustment on the reception signal and a second clock signal obtained by performing a phase adjustment on the first clock signal to extract a second digital signal based on the second clock signal from the reception signal or the reference signal;
a conversion circuit which converts the second digital signal into a third digital signal synchronized with a phase of the first digital signal;
a plurality of comparison circuits each of which is a circuit which shifts a bit sequence of the first digital signal by a predetermined number and counts a number of bit errors by comparing the bit sequence of the first digital signal shifted by the predetermined number with a bit sequence of the third digital signal and in which the predetermined number is set as a mutually different value; and
a selection circuit which selects any one of the plurality of comparison circuits based on the plurality of numbers of bit errors respectively counted by the plurality of comparison circuits and detects the number of bit errors counted by the selected comparison circuit as an actual number of bit errors.

11. The memory controller according to claim 10, wherein
the conversion circuit is a bus width conversion circuit which generates the third digital signal by increasing a bus width of the second digital signal.

12. The memory controller according to claim 10, wherein
the conversion circuit includes
a first-in first-out circuit which sequentially takes in data included in the second digital signal to be stored in a plurality of storage elements and sequentially reads out the data respectively stored in the plurality of storage elements to be output as the third digital signal,
the plurality of storage elements sequentially take in the data included in the second digital signal to be stored based on a clock signal corresponding to the second digital signal, and
the first-in first-out circuit sequentially reads out the data respectively stored in the plurality of storage elements to be output as the third digital signal based on a clock signal corresponding to the first digital signal.

13. The memory controller according to claim 10, further comprising:
a waveform generation circuit which generates a waveform of an eye pattern by comparing the second digital signal with a reference voltage.

14. The memory controller according to claim 10, wherein
the second sampler circuit uses a reference signal obtained by performing a voltage adjustment on the reception signal as the reference signal.

15. A memory system comprising:
a semiconductor storage device;
a memory controller which is connectable to a host and controls the semiconductor storage device;
a first sampler circuit configured to extract a first digital signal based on a first clock signal from a reception signal transmitted from the host;
a second sampler circuit which uses the reception signal or a reference signal obtained by performing an adjustment on the reception signal and a second clock signal obtained by performing a phase adjustment on the first clock signal to extract a second digital signal based on the second clock signal from the reception signal or the reference signal;
a conversion circuit which converts the second digital signal into a third digital signal synchronized with a phase of the first digital signal;
a plurality of comparison circuits each of which is a circuit which shifts a bit sequence of the first digital signal by a predetermined number and counts a number of bit errors by comparing the bit sequence of the first digital signal shifted by the predetermined number with a bit sequence of the third digital signal and in which the predetermined number is set as a mutually different value; and
a selection circuit which selects any one of the plurality of comparison circuits based on the plurality of numbers of bit errors respectively counted by the plurality of comparison circuits and detects the number of bit errors counted by the selected comparison circuit as an actual number of bit errors.

16. The memory system according to claim 15, wherein
the conversion circuit is a bus width conversion circuit which generates the third digital signal by increasing a bus width of the second digital signal.

17. The memory system according to claim 15, wherein
the conversion circuit includes
a first-in first-out circuit which sequentially takes in data included in the second digital signal to be stored in a plurality of storage elements and sequentially reads out the data respectively stored in the plurality of storage elements to be output as the third digital signal,
the plurality of storage elements sequentially take in the data included in the second digital signal to be stored based on a clock signal corresponding to the second digital signal, and
the first-in first-out circuit sequentially reads out the data respectively stored in the plurality of storage elements to be output as the third digital signal based on a clock signal corresponding to the first digital signal.

18. The memory system according to claim 15, further comprising:
a waveform generation circuit which generates a waveform of an eye pattern by comparing the second digital signal with a reference voltage.

19. The memory system according to claim 15, wherein
the second sampler circuit uses a reference signal obtained by performing a voltage adjustment on the reception signal as the reference signal.
